(19) United States
(12) Patent Application Publication
(10) Pub. No.: US 2015/0187889 A1
(43) Pub. Date: Jul. 2, 2015

(54) SURFACE-CONTROLLED SEMICONDUCTOR NANO-DEVICES, METHODS AND APPLICATIONS

(71) Applicant: UNIVERSITY OF ROCHESTER, Rochester, NY (US)

(72) Inventor: Gary W. Wicks, Fairport, NY (US)

(21) Appl. No.: 14/581,187

(22) Filed: Dec. 23, 2014

Related U.S. Application Data
(60) Provisional application No. 61/921,117, filed on Dec. 27, 2013.
(60) Provisional application No. 61/977,803, filed on Apr. 10, 2014.

(51) Int. Cl. H01L 29/205; H01L 29/20

(52) U.S. Cl. CPC H01L 29/205; H01L 29/20

(57) ABSTRACT

Semiconductor structures and semiconductor devices may include: (1) an n-type compound semiconductor material having a surface Fermi level pinned to a conduction band of the n-type compound semiconductor material; (2) a p-type compound semiconductor material having a surface Fermi level pinned to a valence band of the p-type compound semiconductor material; and/or (3) an i-type compound semiconductor materials having a surface Fermi level pinned within a band gap of the i-type compound semiconductor material. Semiconductor structures and semiconductor devices in accordance with the foregoing n-type, p-type and i-type compound semiconductor materials provide the semiconductor structures and semiconductor devices with enhanced performance.

### CROSS-REFERENCE TO RELATED APPLICATIONS

This application is related to, and derives priority from: (1) U.S. Provisional Patent Application Ser. No. 61/921,117, filed 27 Dec. 2013 and titled Surface Controlled Semiconductor Nano-Junction Apparatus, Method and Applications; and (2) U.S. Provisional Patent Application Ser. No. 61/977,803, filed 10 Apr. 2014 and titled Surface Controlled Semiconductor Nano-Junction Apparatus, Methods and Applications, the teachings of both of which applications are incorporated herein fully by reference.

### STATEMENT OF GOVERNMENT SUPPORT

This invention was made with government support under W911NF1110378 awarded by the United States Army Research Office. The government has certain rights in the invention.

### BACKGROUND

1. Field

Embodiments relate generally to semiconductor junction devices. More particularly embodiments relate to relatively small-dimensioned semiconductor junction devices.

2. Description

As semiconductor device dimensions decrease, eventually one reaches a point where alternative physical processes begin to dominate the operation of a semiconductor device. At such small dimensions, conventional device architectures, designed for the processes that operate at larger dimensions, will no longer be useful. It is thus desirable to secure methods and materials that provide enhanced performance of semiconductor junction devices when scaled to smaller dimensions.

### SUMMARY

Attempts to decrease the dimensions of a semiconductor junction device eventually reach a dimension where the semiconductor junction device is no longer operational. This occurs insofar as such smaller dimension semiconductor junction devices are dominated by surface properties, while contemporary semiconductor junction devices are mainly designed according to bulk properties of a semiconductor material. The embodiments that follow describe and illustrate how surface properties of small dimensioned semiconductor material layers may be used rather than traditional bulk properties of semiconductor materials, to design semiconductor junction devices, thereby enabling the construction of operational semiconductor junction devices at smaller dimensions than currently accessible.

In particular, the embodiments utilize when designing and fabricating a semiconductor junction device: (1) a surface controlled n-type compound semiconductor material layer having a surface Fermi level pinned near to a conduction band of the surface controlled n-type semiconductor material layer; (2) a surface controlled p-type compound semiconductor material layer having a surface Fermi level pinned near to a valence band of the surface controlled p-type compound semiconductor material layer; and (3) a surface controlled i-type compound semiconductor material layer having a semi-insulating surface with a surface Fermi level pinned in the bandgap of the surface doped i-type compound semiconductor material layer many kT from either band (i.e., conduction or valence) edge, to in-turn form an operative semiconductor junction device at a semiconductor device junction smaller than currently accessible. Typically the device dimension smaller than currently accessible is intended to include a compound semiconductor device having a semiconductor junction depth and lateral dimensions less than about 250 nanometers.

In addition, the following embodiments also intend that within the embodiments there are included structures that consist of various combinations of the three types of semiconductor material layers listed above, where material layers (1), (2), and (3) above are defined and designated as, “n”, “p”, and “i” layers. Combinations of these material layers produce devices that include, but are not limited to: (1) graded homojunction devices of which n+/n− is a representative but not limiting example; (2) heterojunction devices of which n/p is a representative but not limiting example; (3) intrinsic devices of which n/i/p and n/i/n are representative but not limiting examples.

The embodiments contemplate that semiconductor devices in accordance with the embodiments derive from semiconductor structures in accordance with the embodiments that are electrically energized and thus operational.

A particular semiconductor structure in accordance with the embodiments includes a first semiconductor layer and a second semiconductor layer located in contact over a substrate and comprising different dopant concentrations of one of: (1) a surface controlled n-type compound semiconductor material having a surface Fermi level pinned near to a conduction band of the surface controlled n-type compound semiconductor material; and (2) a surface controlled p-type compound semiconductor material having a surface Fermi level pinned near to a valence band of the surface controlled p-type compound semiconductor material.

Another particular semiconductor structure in accordance with the embodiments includes: (1) a first semiconductor layer located over a substrate and comprising a surface controlled n-type compound semiconductor material having a surface Fermi level pinned near to a conduction band of the surface controlled n-type compound semiconductor material; and (2) a second semiconductor layer located over the substrate, contacting the first semiconductor layer and comprising a surface controlled p-type compound semiconductor material having a surface Fermi level pinned near to a valence band of the surface controlled p-type compound semiconductor material.

Yet another particular semiconductor structure in accordance with the embodiments includes a first semiconductor layer and a second semiconductor layer located over a substrate and comprising at least one of: (1) a surface controlled n-type compound semiconductor material having a surface Fermi level pinned near to a conduction band of the surface controlled n-type compound semiconductor material; and (2) a surface controlled p-type compound semiconductor material having a surface Fermi level pinned near to a valence band of the surface controlled p-type compound semiconductor material. This other particular semiconductor structure also includes a third semiconductor layer located over the substrate and interposed between and contacting the first semiconductor layer and the second semiconductor layer, and comprising a surface controlled i-type compound semiconductor material having a Fermi level pinned within a band gap of the surface controlled i-type compound semiconductor material.

### BRIEF DESCRIPTION OF THE DRAWINGS

The objects, features and advantages of the embodiments are understood within the context of the Detailed Description of the Non-Limiting Embodiments, as set forth below. The Detailed Description of the Non-Limiting Embodiments is understood within the context of the accompanying drawings, which form a material part of this disclosure, wherein:

FIG. 1 shows a near surface band diagram of a semiconductor that has its surface Fermi level pinned in the bandgap, thereby creating a semi-insulating surface. The bulk conductivity may be n-type (on left) or p-type (on right), but the surface is always a depletion layer i.e., semi-insulating. L is the thickness of the surface depletion region; φ is the Schottky Barrier height.

FIG. 2 shows that as its diameter is reduced, a conventional pn junction loses its bulk p- and n-regions, leaving only a surface-controlled region. In a typical semiconductor, such as GaAs, the surface controlled layer is depleted of mobile carriers.

FIG. 3 shows band edges and energies of a surface Fermi level pinning in common III-V semiconductors.

FIG. 4 shows near-surface band diagrams of a semiconductor that has its surface Fermi level pinned in or near the conduction band, thereby creating an n-type surface. The bulk conductivity may be n-type (on left) or p-type (on right), but the surface is always has n-type conductivity.

FIG. 5 shows near-surface band diagrams of a semiconductor that has its surface Fermi level pinned in/near to the valence band. The bulk conductivity may be p-type (on left) or n-type (on right), but the surface is always has p-type conductivity.

FIG. 6 shows a nanowire p/n radial junction in an n-surface material, such as InAs, which is doped p-type.

FIG. 7 shows evolution from larger diameter GaSb/InAs mesas to a nanowire axial p/n junction. Even when the device is small enough so that no bulk conductivity remains and doping is not useful, a p/n junction still exists because of surface control of the conductivity.

FIG. 8 shows band diagram of an axial p/n junction formed of GaSb and InAs. Electrons from the top of the valence band will readily tunnel into the conduction band of InAs, creating a large leakage current.

FIG. 9 shows band diagram of a p/i/n axial nano-junction consisting of GaSb/GaInAsSb (or GaSb/InAs superlattice)/InAs. The GaInAsSb layer has its surface Fermi level pinned in the bandgap, and thus forms an intrinsic layer in a surface-dominated junction. The GaInAsSb layer widens the tunnel barrier of a simple GaSb/InAs structure, thereby suppressing leakage current.

### DETAILED DESCRIPTION OF THE NON-LIMITING EMBODIMENTS

The embodiments that follow describe a particular advanced semiconductor junction device (and related structure) with reduced dimensions and a particular design rule methodology for fabricating the advanced semiconductor junction device (and related structure) with reduced dimensions.

Within the embodiments that follow semiconductor materials are described in terms of: (1) a surface controlled n-type compound semiconductor material having a surface Fermi level pinned near to a conduction band of the surface controlled n-type compound semiconductor material; (2) a surface controlled p-type compound semiconductor material having a surface Fermi level pinned near to a valence band of the surface controlled p-type compound semiconductor material; and (3) a surface controlled i-type compound semiconductor material having a surface Fermi level pinned within a band gap of the surface controlled i-type compound semiconductor material.

Within the context of the foregoing terminology, the “near to” pinning of the surface Fermi level with respect to the conduction band or the valance band for the surface controlled n-type compound semiconductor material or the surface controlled p-type compound semiconductor material, respectively, is intended to provide a distance of the Fermi level with respect to either the conduction band or the valence band of less than about 0.125 eV. Moreover, the pinning of the Fermi level with respect to the band gap of the surface controlled i-type compound semiconductor material is intended that the Fermi level is at least about and preferably more than about 0.3 eV from either a valance band or a conduction band within the surface controlled i-type compound semiconductor material.

Within the context of the embodiments, the surface-controlled n-type compound semiconductor material is selected from the group including but not limited to InN, GaInN, AlInN, InAs, InAsSb, GaInAs, AlInAs, GaInAsSb, AlInAs, AlGaInAs, AlInAsSb and InAsP surface controlled n-type compound semiconductor materials.

Within the context of the embodiments, the surface-controlled p-type compound semiconductor material is selected from the group including but not limited to GaSb, InSb, GaInSb, GaAsSb, InAsSb, GaInAsSb, GaPSb, InPSb, AlGaSb, AlInSb, AlGaAsSb and AlInAsSb surface-controlled p-type compound semiconductor materials.

Within the context of the embodiments the surface-controlled i-type compound semiconductor material is selected from the group including but not limited to AlN, GaN, AlGaN, AlInN, GaInN, AlGaInN, AlP, GaP, InP, AlGaP, AlInP, GaInP, AlAs, GaAs, AlGaAs, AlSb, AlGaSb, GaAsP, AlAsP, GaPSb, AlPSb, GaInSb, GaAsSb, InAsSb, GaInAsSb, GaPSb, InPSb, AlGaSb, AlInSb, AlGaAsSb, AlInAsSb and AlAsSb surface-controlled i-type compound semiconductor materials.

As is further understood by a person skilled in the art, semiconductor structures and semiconductor devices in accordance with the embodiments may be fabricated into the classes or categories of semiconductor structures and devices that include but are not limited to: (1) graded homojunction structures and devices of which n+/n− is representative but not limiting; (2) heterojunction structures and devices of which n/p is representative but not limiting; and (3) intrinsic junction structures and devices of which n/i/n and n/i/p are representative but not limiting. Embodiments also consider junction structures and junction devices, which include any combination of the foregoing junction structures and junction devices.

Semiconductor structures and semiconductor devices in accordance with the embodiments may be fabricated using photolithography methods as are conventional in the art with respect to the foregoing dimensional limitation of at least as low as about, and generally less than about 250 nanometers. These photolithography methods may be augmented with or replaced with methods such as but not limited to ion implantation methods, thermal diffusion methods, wet or dry etching methods and electron beam lithography methods, that provide for definition or growth of nanowires.

### 1. Explanation of the Innovation, Objectives, and Expected Significance

### 1.1 Overview

Attempts to decrease the dimensions of a semiconductor device eventually reach a size where the device is no longer operational. This occurs because such small devices are dominated by surface properties, but present day devices are mainly designed according to the bulk properties of the semiconductor. This proposal describes how to use surface properties, rather than the traditional bulk properties, to design semiconductor devices, thereby enabling the construction of operational devices that are smaller than ever before.

### 1.2 Description of the Fundamental Cause of the Problem

The continuing advancement of semiconductor technology includes making devices ever smaller. As the size of a semiconductor structure is reduced, the bulk region shrinks and eventually vanishes, leaving only the surface region. Thus, reducing size causes a transition from bulk-controlled to surface-controlled characteristics. In conventional compound semiconductors, this transition from bulk-control to surface-control causes a complete, usually unwanted, change in electrical properties, since bulk and surface electrical conductivities are independent and, in general, quite different.

Bulk conductivity is engineered through the use of doping, which is used to make n-type and p-type conductivities—the foundation of conventional semiconductor device technology. On the other hand, the surface conductivity in compound semiconductors is independent of doping, instead being determined by the pinning of the surface Fermi level. In most common compound semiconductors, the surface Fermi level is pinned well inside the bandgap, thus the most surfaces regions are depletion layers, regardless of whether the bulk conductivity is n-type or p-type.

Nanostructures (nano-wires, nano-posts, nano-cylinders, and nano-mesas) are good vehicles to explore these effects because their range of diameters span the transition from bulk-control to surface-control. Larger diameter nanostructures typically have both bulk- and surface-controlled regions: a conducting bulk-controlled core, with an outer surface-controlled layer. Smaller diameter nanowires have no bulk conductivity core. In many semiconductor materials, these smaller nanowires exhibit conductivity that is many orders of magnitude smaller than the bulk and are completely surface-depleted of mobile carriers. In such a small diameter nanowire, if a p/n junction were attempted by the usual doping techniques, it would not have any bulk p or n regions remaining, but would instead be totally depleted by the surface—no pn junction would exist despite the doping.

### 1.3 Statement of the Problem

The above discussion points to a major problem in the quest of creating a technology of semiconductor nano-devices. At present there is a minimum size limit for functional semiconductor devices, which occurs when the conductivity is no longer dominated by bulk conductivity, but instead surface conductivity becomes the main conduction mechanism.

As device dimensions are reduced, a point is reached where the semiconductor's conductivity becomes completely controlled by the surface. At this dimension and smaller, doping is no longer useful to engineer p- or n-type conductivities, and conventional pn junctions, and related doping-controlled devices are no longer operational.

### 1.4 Objective

A new design approach is needed to be able to pass through this minimum size limit for operational semiconductor nano-devices. The approach is described in the embodiments. Briefly, rather than using doping to make n- and p-regions, semiconductor materials that naturally have n-type surfaces and others with p-type surfaces and others with i-surfaces (semi-insulating or depleted surfaces) will be used to create n-type and p-type and i-type conductivities in nano-devices.

### 1.5 Expected Significance

The design rules illustrated in accordance with the embodiments will enable breaking the semiconductor device size barrier that limits how small an operational device can be. This will be accomplished by moving from the conventional approach of using doping to control electrical conductivities to the presently proposed concept of surface control of conductivity. The concepts apply readily to any fabrication technology for semiconductor nano-devices, such as the top-down fabrication schemes of focused ion beam etching or e-beam lithography, and the bottom-up approaches such as epitaxial growth of nano-wires. It will enable the continued shrinking of device dimensions beyond the present minimum size limit, opening the door to a wide collection of operational devices on the scale of tens of nanometers, such as nano-rectifiers, nano-LED's, nano-lasers, nano-photodetectors, and nano-bipolar-transistors. Future applications of these nano-devices are widespread: examples include increased density of integrated circuits, bio- and chemical-sensors, advanced energy-producing photovoltaics, optical-antenna enhanced emitters and detectors, and combinations of plasmonics with semiconductor nano-devices.

### 2. Technical Description

Both bulk and surface conductivities are controlled by the location of the Fermi level at the respective locations. However, different mechanisms determine the location of the Fermi level in the bulk and at the surface. In the bulk, the Fermi level location is determined by doping. At the surface of a compound semiconductor, the Fermi level is pinned at a fixed energy that is characteristic of the particular semiconductor material, and is independent of doping. The ability to create p- and n-type conductivities in ultra small, surface-controlled semiconductor devices requires being able to engineer the location of the surface Fermi level (relative to the band edges).

### 2.1 Background: Surface Characteristics of Compound Semiconductors

### 2.1.1 Depleted Surface Materials

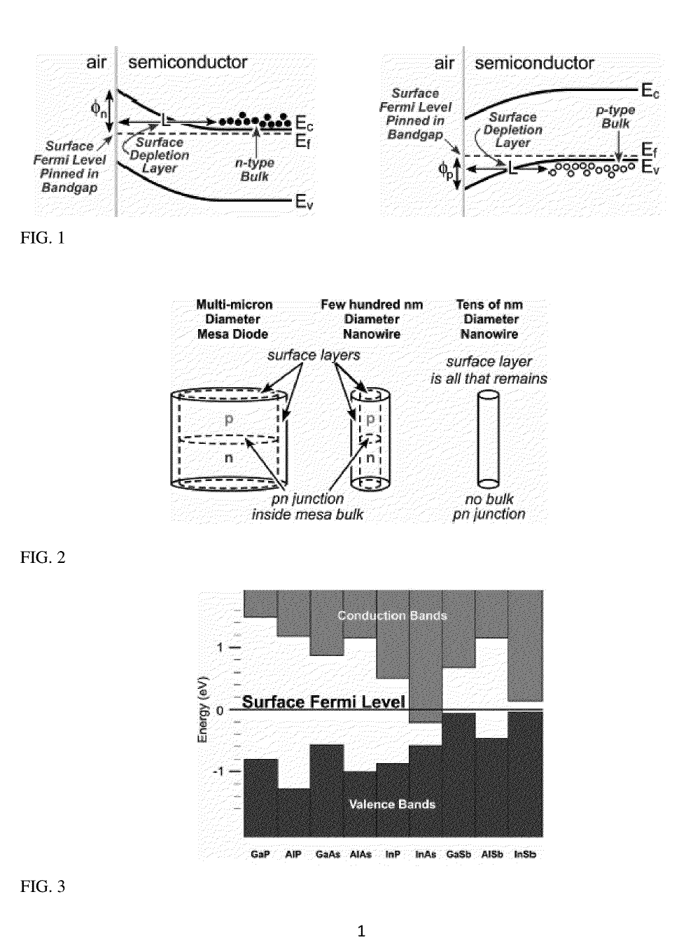

Most compound semiconductors, such as GaAs, have their surface Fermi levels pinned well inside the bandgap, thereby depleting the surface of mobile current carriers, regardless of whether the bulk is doped n-type or p-type. The band diagrams showing both the bulk conducting regions and the depleted surface regions are displayed in FIG. 1.

The band bending near the surface creates a Schottky barrier with a height, φ, determined by the energy difference between the surface level and the conduction band or valence band in n-type or p-type material, respectively. The thickness of the surface depletion region, L_{dep}, is determined by the Schottky barrier height, the semiconductor's dielectric constant, and the doping density, N_{d}:

$${L}_{dep} = \sqrt{\frac{2 ɛφ}{{e}^{2} {N}_{d}}}$$

Typical magnitudes of surface depletion lengths in GaAs are shown below in Table 1.

TABLE 1

| | Surface Depletion |
|---|---|
| Doping Density | Thickness, L_{dep} |
| (cm⁻³) | (nm) |
| 10¹⁷ | 75 |
| 10¹⁸ | 25 |

To be strictly correct, the above equation for L_{dep} and the values shown in Table 1 are calculated for a planar geometry, appropriate for wafers and epitaxial layers. Surface depletion lengths for the cylindrical geometry of a nanostructure have been modeled, however the results are not substantially different from those of the planar geometry.

This phenomenon of surface depletion has the following importance to the present embodiment:

When the diameter of a GaAs nanowire is less than 2L_{dep}, the nanostructure is totally surface-depleted, i.e., bulk (doping-determined) conductivity vanishes.

Consider the problem of attempting to make a nanostructure pn junction device in a typical compound semiconductor such as GaAs. At large device diameters, the core of the nanostructure will have bulk p- and n-regions, and exhibit the familiar properties of a pn junction, such as electrical rectification. However at small diameters (less than 2L_{dep}), the p- and n-type regions disappear and all that remains is the surface-controlled depletion region, as shown in FIG. 2.

### 2.1.2 General Surface Characteristics of III-V Compound Semiconductors

The location of the surface Fermi levels in semiconductor materials is crucial to the present problem. The surface Fermi level in III-V binary compounds is shown in FIG. 3.

As described earlier, and shown in the FIG. 3, most semiconductors, such as GaAs, have the surface Fermi Level pinned well inside the bandgap, making their surfaces depleted of carriers. But not all semiconductors have depleted surfaces. A few have the surface Fermi level pinned in/near the conduction band or valence band, thereby making the surface n-type or p-type, respectively. Thus, the surface characteristics of compound semiconductors can be grouped into 3 categories, depending on whether the surface Fermi level is pinned in or near the bandgap, in or near the conduction band, or in or near the valence band as shown in Table 2, which categorizes binary compound semiconductors by their surface conductivity type. More complicated ternary, quaternary, and quinary compounds are also possible, and increase the material possibilities.

TABLE 2

| Surface Fermi Level | Surface Fermi Level | Surface Fermi Level |
|---|---|---|
| in Bandgap | in/near Conduction Band | in/near Valence Band |
| (Depleted Surface) | (N-type Surface) | (P-type Surface) |
| AlN | InN | GaSb |
| GaN | InAs | InSb |
| AlP | | |
| GaP | | |
| InP | | |
| AlAs | | |
| GaAs | | |

### 2.1.3 N-Surface Semiconductor Materials

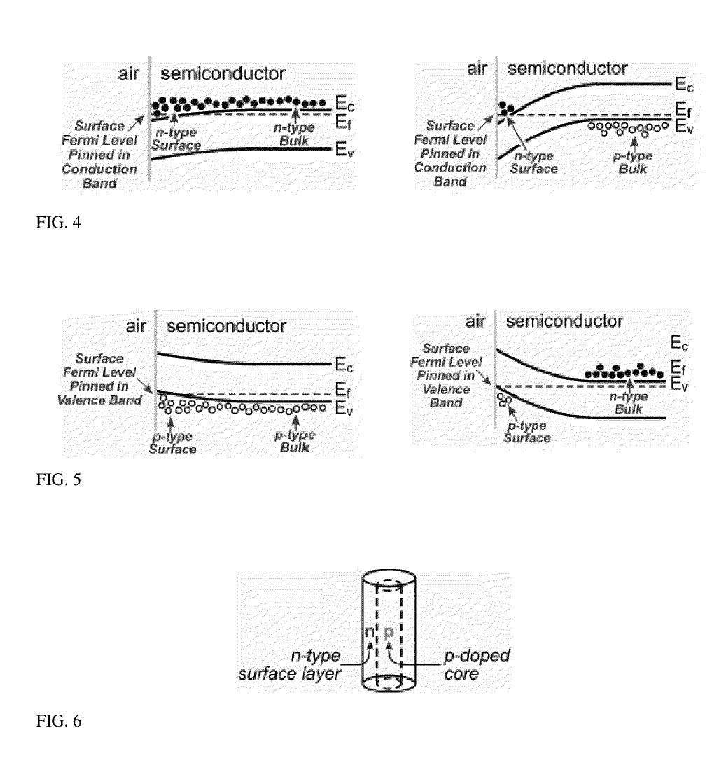

The semiconductors, InN and InAs, have their surface Fermi level pinned in the conduction band, there producing mobile electrons in their surface regions, as shown in the band diagrams of FIG. 4.

In n-surface materials that are n-doped, there is continuous n-type conductivity from the bulk to the surface region, although the electron concentration will, in general, change as the bulk electron concentration is determined by the donor doping concentration and the surface electron concentration is determined by the location of the surface Fermi level pinning. In n-surface p-doped materials, the bulk is p-type, the surface is n-type and there is a depletion region in the transition from bulk to surface regions.

### 2.1.4 P-Surface Semiconductor Materials

Just the reverse of n-surface materials, the semiconductor materials, such as GaSb and InSb, which have their surface Fermi level pinned in (or near) the valence band, will have p-type surfaces, regardless of doping and bulk conductivity, as shown in FIG. 5.

### 2.2 Design of Surface-Controlled pn Nano-Junctions

The design of surface controlled pn nano-junctions must be based on surface conductivity types, not on bulk (doping-determined) conductivity types. The prototype materials for building surface-controlled nanodevices are InAs (n-surface) and GaSb (p-surface). By using these two materials to create n- and p-type surface-controlled conductivities, rather than relying on doping, operational ultra-small pn junctions can be made.

### 2.2.1 Nanowire pn Radial Junctions

An interesting pn nanowire structure is one with a larger diameter (so that some bulk conductivity still remains in its core), which is constructed of an n-surface material, such as InAs, that is doped p-type. Such a nanowire is a pn radial junction, and is shown in FIG. 6.

A reverse polarity pn radial junction could also be created using a p-surface material, e.g., GaSb, which is doped n-type. Such pn radial junctions are hybrids—one conductivity type is bulk (doping) controlled, the other conductivity type is surface controlled. Since these radial pn junctions required bulk conductivity on one side of the junction, they cannot be made in the smallest dimensions where bulk conductivity vanishes. While they may have other applications, they do not address the purpose of this proposal to create devices smaller than the present limit determined by the disappearance of bulk control of conductivities.

### 2.2.2 Nanowire pn Axial Junctions

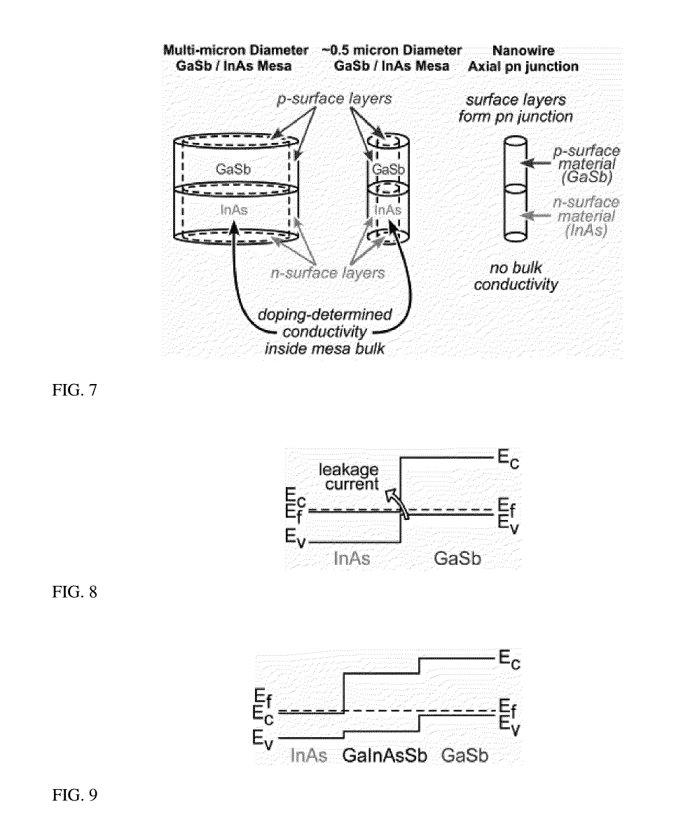

A pn junction that is totally surface-controlled can be made in nanowire that consists of an axial heterojunction of a p-surface material and an n-surface material. The best choice of materials is GaSb (p-surface) and InAs (n-surface). FIG. 7 shows that as larger diameters GaSb/InAs heterojunction mesas are shrunk down to the nanoscale, a pn junction still exists due to the surface characteristics of the two materials.

2.2.2.1 Nanowire p-i-n Axial Junctions

The pn nano-junction shown in FIG. 7 will suffer from excessive leakage current, as electrons from the top of the valence band on the p-side (GaSb) will easily tunnel into the conduction band of the n-side (InAs), as shown in FIG. 8.

This band-to-band tunneling leakage current will degrade most practical applications, such as its use as a rectifier, photodiode or LED. To block the leakage current, an intrinsic layer must be inserted between the n-layer (InAs in this example) and the p-layer (GaSb in this example) to widen the barrier and suppress tunneling. One way to form such an intrinsic layer is to use a material that is an interpolation between InAs and GaSb, such as the GaInAsSb quaternary or an InAs/GaSb superlattice. Such materials will have their surface Fermi level pinned in or near the bandgap, and thus be surface-depleted (intrinsic) materials. The resulting band structure of such a p-i-n axial nano-junction is shown in FIG. 9.

All references, including publications, patent applications, and patents cited herein are hereby incorporated by reference in their entireties to the same extent as if each reference was individually and specifically indicated to be incorporated by reference and were set forth in its entirety herein.

The use of the terms “a” and “an” and “the” and similar referents in the context of describing the embodiments (especially in the context of the following claims) is to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. The term “connected” is to be construed as partly or wholly contained within, attached to, or joined together, even if there is something intervening.

The recitation of ranges of values herein are merely intended to serve as a shorthand method of referring individually to each separate value falling within the range, unless otherwise indicated herein, and each separate value is incorporated into the specification as if it was individually recited herein.

All methods described herein can be performed in any suitable order unless otherwise indicated herein or otherwise clearly contradicted by context. The use of any and all examples, or exemplary language (e.g., “such as”) provided herein, is intended merely to better illuminate embodiments and does not impose a limitation on the scope of the embodiments unless otherwise claimed.

No language in the specification should be construed as indicating any non-claimed element as essential to the practice of the embodiments.

It will be apparent to those skilled in the art that various modifications and variations can be made to the present embodiments without departing from the spirit and scope of the embodiments. There is no intention to limit the embodiments to the specific form or forms disclosed, but on the contrary, the intention is to cover all modifications, alternative constructions, and equivalents falling within the spirit and scope of the embodiments, as defined in the appended claims. Thus, it is intended that the present embodiments cover the modifications and variations of this embodiment provided they come within the scope of the appended claims and their equivalents.

What is claimed is:

1. A semiconductor structure comprising:
a first semiconductor layer and a second semiconductor layer located in contact over a substrate and comprising different dopant concentrations of one of:
a surface controlled n-type compound semiconductor material having a surface Fermi level pinned near to a conduction band of the surface controlled n-type compound semiconductor material; and
a surface controlled p-type compound semiconductor material having a surface Fermi level pinned near to a valence band of the surface controlled p-type compound semiconductor material.

2. The semiconductor structure of claim 1 wherein the semiconductor structure is selected from the group consisting of p+/p− and n+/n− semiconductor structures.

3. The semiconductor structure of claim 1 wherein the surface controlled n-type compound semiconductor material is selected from the group consisting of InN, GaInN, AlInN, InAs, InAsSb, GaInAs, AlInAs, GaInAsSb, AlInAs, AlGaInAs, AlInAsSb and InAsP surface controlled n-type compound semiconductor materials.

4. The semiconductor structure of claim 1 wherein the surface controlled p-type compound semiconductor material is selected from the group consisting of GaSb, InSb, GaInSb, GaAsSb, InAsSb, GaInAsSb, GaPSb, InPSb, AlGaSb, AlInSb, AlGaAsSb and AlInAsSb surface controlled p-type compound semiconductor materials.

5. The semiconductor structure of claim 1 further comprising a surface controlled i-type semiconductor material layer having a surface Fermi level pinned in a bandgap of the surface controlled i-type semiconductor material contacting one of the first semiconductor layer and the second semiconductor layer.

6. The semiconductor structure of claim 1 further comprising a third semiconductor layer comprising the other of the surface controlled p-type semiconductor material and the surface controlled-type semiconductor material contacting one of the first semiconductor layer and the second semiconductor layer.

7. A semiconductor structure comprising:
a first semiconductor layer located over a substrate and comprising a surface controlled n-type compound semiconductor material having a surface Fermi level pinned near to a conduction band of the surface controlled n-type compound semiconductor material; and
a second semiconductor layer located over the substrate, contacting the first semiconductor layer and comprising a surface controlled p-type compound semiconductor material having a surface Fermi level pinned near to a valence band of the surface controlled p-type compound semiconductor material.

8. The semiconductor structure of claim 7 wherein the semiconductor structure is selected from the group consisting of n/p, p/n, n+/n−/p, n−/n+/p, p+/p−/n and p−/p+/n semiconductor structures.

9. The semiconductor structure of claim 7 wherein the surface-controlled n-type compound semiconductor material is selected from the group consisting of InN, GaInN, AlInN, InAs, InAsSb, GaInAs, AlInAs, GaInAsSb, AlInAs, AlGaInAs, AlInAsSb and InAsP surface controlled n-type compound semiconductor materials.

10. The semiconductor structure of claim 7 wherein the surface-controlled p-type compound semiconductor material is selected from the group consisting of GaSb, InSb, GaInSb, GaAsSb, InAsSb, GaInAsSb, GaPSb, InPSb, AlGaSb, AlInSb, AlGaAsSb and AlInAsSb surface controlled p-type compound semiconductor materials.

11. The semiconductor structure of claim 7 wherein the first semiconductor layer and the second semiconductor layer are co-axial.

12. The semiconductor structure of claim 11 wherein the first semiconductor layer and the second semiconductor layer comprise co-axially nested cylinders.

13. The semiconductor structure of claim 11 wherein the first semiconductor layer and the second semiconductor layer abut linearly.

14. A semiconductor structure comprising:
a first semiconductor layer and a second semiconductor layer located over a substrate and comprising at least one of:
a surface controlled n-type compound semiconductor material having a surface Fermi level pinned near to a conduction band of the surface controlled n-type compound semiconductor material; and
a surface controlled p-type compound semiconductor material having a surface Fermi level pinned near to a valence band of the surface controlled p-type compound semiconductor material; and
a third semiconductor layer located over the substrate and interposed between and contacting the first semiconductor layer and the second semiconductor layer, and comprising a surface controlled i-type compound semiconductor material having a Fermi level pinned within a band gap of the surface controlled i-type compound semiconductor material.

15. The semiconductor structure of claim 14 wherein the semiconductor structure is selected from the group consisting of n/i/p, p/i/n, p/i/p and n/i/n semiconductor structures.

16. The semiconductor structure of claim 14 wherein the surface-controlled n-type compound semiconductor material is selected from the group consisting of InN, GaInN, AlInN, InAs, InAsSb, GaInAs, AlInAs, GaInAsSb, AlInAs, AlGaInAs, AlInAsSb and InAsP surface controlled n-type compound semiconductor materials.

17. The semiconductor structure of claim 14 wherein the surface-controlled p-type compound semiconductor material is selected from the group consisting of GaSb, InSb, GaInSb, GaAsSb, InAsSb, GaInAsSb, GaPSb, InPSb, AlGaSb, AlInSb, AlGaAsSb and AlInAsSb surface controlled p-type compound semiconductor materials.

18. The semiconductor structure of claim 14 wherein the surface-controlled i-type compound semiconductor material is selected from the group consisting of AlN, GaN, AlGaN, AlInN, GaInN, AlGaInN, AlP, GaP, InP, AlGaP, AlInP, GaInP, AlAs, GaAs, AlGaAs, AlSb, AlGaSb, GaAsP, AlAsP, GaPSb, AlPSb, GaInSb, GaAsSb, InAsSb, GaInAsSb, GaPSb, InPSb, AlGaSb, AlInSb, AlGaAsSb, AlInAsSb and AlAsSb surface controlled i-type compound semiconductor materials.

19. The semiconductor structure of claim 14 wherein the semiconductor structure is selected from the group consisting of n/i/p and p/i/n semiconductor structures.

20. The semiconductor structure of claim 14 wherein the semiconductor structure is selected from the group consisting of n/i/n and p/i/p semiconductor structures.
